(19) United States
(12) Patent Application Publication
(10) Pub. No.: US 2013/0049058 A1
(43) Pub. Date: Feb. 28, 2013

(54) LED MODULE

(71) Applicant: Masahiko Kobayakawa, Kyoto (JP)

(72) Inventor: Masahiko Kobayakawa, Kyoto (JP)

(73) Assignee: ROHM CO., LTD., Kyoto-shi, Kyoto (JP)

(21) Appl. No.: 13/695,201

(22) PCT Filed: Apr. 28, 2011
(86) PCT No.: PCT/JP2011/060434

§ 371 Date: Oct. 29, 2012

(30) Foreign Application Priority Data
Apr. 30, 2010 (JP) 2010-104766

(51) Int. Cl. H01L 33/62; H01L 33/60

(52) U.S. Cl. 257/98; 257/99; 257/E33.066; 257/E33.072

(57) ABSTRACT

An LED module A1 includes a first lead 1 with a mount surface 12a at a die-bonding portion 12, a second lead 2 with a wire-bonding portion 22 and having a thickness direction corresponding to that of the lead 1, and an LED chip 3 on the mount surface 12a, with a first electrode terminal 31 connected to the first lead 1, and a second electrode terminal 32 connected to the second lead 2. A support member 4 supports the leads 1, 2, The second terminal 32 is on a thickness-side surface of the LED chip 3 and connected to the wire-bonding portico 22 with a wire 61. The support member 4 includes a protective portion 42 covering a thickness-side surface of the first lead 1 with the mount surface 12a exposed. The die-bonding portion 12 bulges, in the thickness direction, relative to portions of the first lead 1 covered by the protective portion 42. The arrangements provide a longer lifetime and ensures reliability and proper light emission.

### TECHNICAL FIELD

The present invention relates to an LED module incorporating an LED chip.

### BACKGROUND ART

FIG. 8 shows an example of conventional LED module (see e.g. Patent Document 1). The LED module X shown in FIG. 8 includes leads 91 and 92, an LED chip 93, a support member 94 and a light-transmitting member 95. The LED chip 93 is bonded to the lead 91 with a bonding material, not shown. The LED chip 93 has a pair of electrodes on the upper surface in FIG. 8, and the electrodes are connected to the leads 91 and 92 via wires 96 and 97. The support member 94 is made of e.g. a resin and formed by insert molding using a mold to cover part of the leads 91, 92. The light-transmitting member 95 is made of a resin that transmits light from the LED chip 93, and protects the LED chip 93 and the wires 96 and 97. The characteristics of the light to be emitted from the LED module X, such as color or brightness of the light, are adjusted by adding various substances to the light-transmitting member 95. As shown in FIG. 8, the support member 94 has a reflective surface 94a that reflects light traveling sideways from the LED chip 93 in the figure upward.

In this type of LED module X, the surfaces of the leads 91 and 92 are sometimes plated with silver for enhancing the heat conductivity and electric conductivity, However, when plated with silver, the surfaces sometimes change to a dark color as time elapses. Such color change of the surfaces of the leads 91, 92 results in change in characteristics of the light emitted from the LED module X, which shortens the time period during which the LED module X can be used properly.

To avoid the above-described adverse effects of the color change/protective portions 94b may be provided to cover the leads 91 and 92, as shown by phantom lines in FIG. 8. In such a case, however, in the process of setting the wires 96 and 97, the wires 96 and 97 are sometimes broken due to contact with the protective portions 94b. Moreover, the light, which should be reflected by the reflective surface 94a arranged on a side of the LED chip 93 and emitted upward in FIG. 8, is sometimes unduly blocked by the protective portions 94b.

### TECHNICAL REFERENCE

### Patent Document

Patent Document 1: JP-A-2004-127988

### SUMMARY OF THE INVENTION

### Problems to be Solved by the Invention

The present invention has been conceived under the circumstances described above. It is therefore an object of the present invention to provide an LED module that can achieve a long lifetime without reducing the reliability and light emission amount.

### Means for Solving the Problems

According to a first aspect of the present invention, there is provided an LED module comprising: a first lead including a die-bonding portion provided with a mount surface disposed on one side in a thickness direction; a second lead including a wire-bonding portion and spaced apart from the first lead, the second lead being arranged such that a thickness direction thereof corresponds to the thickness direction of the first lead; an LED chip mounted on the mount surface and provided with, a first electrode terminal and a second electrode terminal, the first electrode terminal being electrically connected to the first lead, the second electrode terminal being electrically connected to the second lead; and a support member supporting the first lead and the second lead. The LED chip includes an end surface disposed on the one side in the thickness direction, and the second electrode terminal, is provided on the end surface and connected to the wire-bonding portion by a wire. The support member includes a protective portion, and the first lead includes a surface disposed on the one side in the thickness direction, the protective portion covering the above-mentioned surface of the first lead in a manner such that the mount surface is exposed. The die-bonding portion bulges toward the one side in the thickness direction relative to portions of the first lead that are covered by the protective portion.

According to a second aspect of the present invention, in the LED module or the first aspect, the protective portion includes an inclined portion that becomes thinner as proceeding away from the die-bonding portion in a direction in which the wire extends.

According to a third aspect of the present invention, in the LED module of the second aspect, the inclined portion is configured to overlap a part of the second lead as viewed in the thickness direction.

According to a fourth aspect of the present invention, in the LED module of any one of the first through the third aspects, the wire-bonding portion is metal-plated on the one side in the thickness direction,

According to a fifth aspect of the present invention, in the LED module of any one of the first through the fourth aspects, the first electrode terminal is bonded to the die-bonding portion.

According to a sixth aspect of the present invention, in the LSD module of any one of the first through the fourth aspects, the first electrode terminal is provided on a portion of the LED chip disposed on the one side in the thickness direction, the first lead includes at wire-bonding portion connected to the first electrode terminal with an additional wire, and the protective portion is configured to expose the wire-bonding portion of the first lead.

According to a seventh aspect of the present invention, in the LED module or the sixth aspect, the protective portion includes an additional inclined portion that becomes thinner as proceeding away from the die-bonding portion in a direction in which the additional wire extends.

According to an eighth aspect of the present invention, in the LED module of the sixth or seventh aspect, the wire-bonding portion of the first lead is metal-plated on the one side in the thickness direction.

According to a ninth aspect of the present invention, in the LED module of any one of the first through the eighth aspects, the support member is made of a resin that reflects light emitted from the LED chip and includes a reflective surface inclined to become further away from the LED chip in the thickness direction as proceeding away from the LED chip in a direction perpendicular to the thickness direction.

According to a tenth aspect of the present invention, in the LED module of the ninth aspect, the reflective surface is in the form of a frame surrounding the LED chip as viewed in the thickness direction, and the protective portion is connected to the reflective surface.

According to an eleventh aspect of the present invention, in the LED module of the tenth aspect, the reflective surface includes an inner edge in the form of an elongated rectangle as viewed in the thickness direction, and the LED chip is arranged at a center in a short-side direction of the inner edge.

According to a twelfth aspect of the present invention, in the LED module of the eleventh aspect, the LED chip is arranged at a center in a longitudinal direction of the inner edge.

According to a thirteenth aspect of the present invention, in the LED module of any one of the first through the twelfth aspects, the end surface of the LED chip on the one side in the thickness direction is offset toward the one side in the thickness direction relative to a surface of the protective portion.

According to a fourteenth aspect of the present invention, in the LED module of the thirteenth aspect, the die-bonding portion is offset toward the one side in the thickness direction relative to the surface on the one side of the protective portion.

According to a fifteenth aspect of the present invention, in the LED module of any one of the first through the fourteenth aspects, the first lead is bent so that a part thereof projects toward the one side in the thickness direction and the projecting part provides the die-bonding portion.

According to a sixteenth aspect of the present invention, there is provided an LED module comprising: a first lead including a die-bonding portion and a root sunk portion, the die-bonding portion being provided with a mount surface disposed on a first side in a thickness direction, the root sunk portion being offset toward a second side in the thickness direction relative to the die-bonding portion; a second lead including a wire-bonding portion and spaced apart from the first lead, the second lead being arranged such that a thickness direction of the wire-bonding portion corresponds to the thickness direction of the bonding portion of the first lead; an LED chip mounted On the mount surface and including at first electrode terminal and a second electrode terminal, the first electrode terminal being electrically connected to the first lead, the second electrode terminal being disposed on the first side in the thickness direction and electrically connected to the second lead; a wire connecting the second electrode terminal and the wire-bonding portion to each other; and a support member supporting the first lead and the second lead and including a protective portion covering the root sunk portion in at manner such that the mount surface is exposed.

According to this arrangement, since the first lead and the second lead are covered by the protective portion, adverse effects of the color change of the first lead and the second lead on the characteristics of the light to be emit ted are suppressed. Therefore, the LED module of the present invention has a long lifetime without deteriorating reliability and light emission amount.

Other features and advantages of the present invention become clearer from detailed description given below with reference to the accompanying drawings.

### BRIEF DESCRIPTION OF THE DRAWINGS

FIG. 1 is a plan view showing an LED module according to a first embodiment of the present invention;

FIG. 2 is a sectional view taken along lines II-II in FIG. 1;

FIG. 3 is a sectional view taken along lines III-III in FIG. 1;

FIG. 4 is a plan view showing an LED module according to a second embodiment of the present invention;

FIG. 5 is a sectional view taken along lines V-V in FIG. 4;

FIG. 6 is a plan view showing an LED module according to a third embodiment of the present invention;

FIG. 7 is a sectional view taken along lines VII-VII in FIG. 6; and

FIG. 8 is a sectional view showing an example of conventional LED module.

### MODE FOR CARRYING OUT THE INVENTION

Preferred embodiments of the present invention are described below with reference to the accompanying drawings.

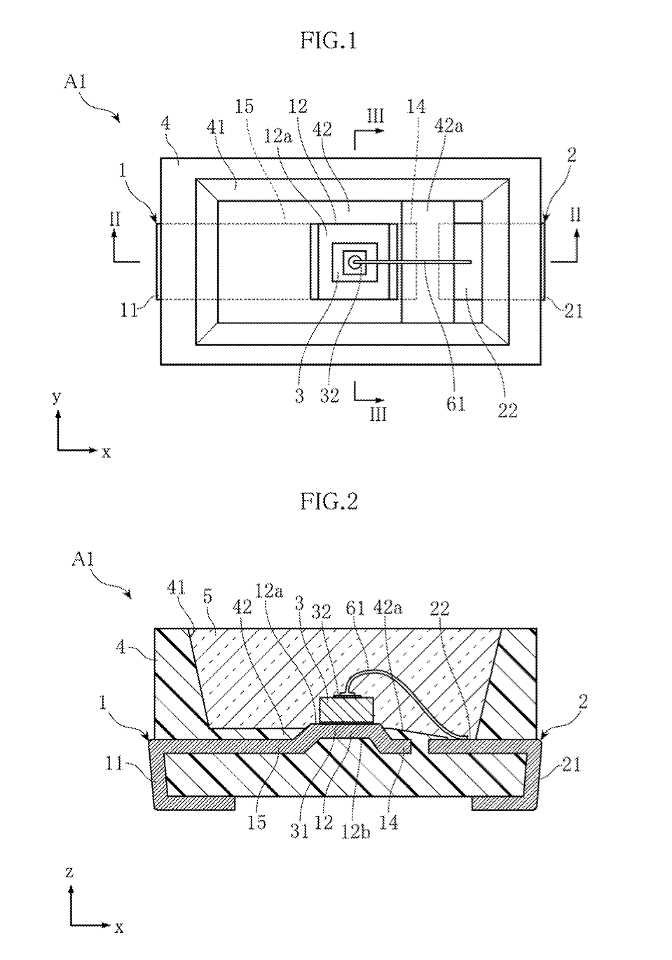

FIGS. 1-3 show an LED module according to a first embodiment of the present invention. The LED module A1 of this embodiment includes leads 1 and 2 electrically insulated from each other, an LED chip 3, a support member 4 supporting the leads 1 and 2, a light-transmitting member 5 covering the LED chip 3, and a wire 61. The LED module A1 is designed such that the LED chip 3 emits light due to connection of the leads 1 and 2 to an external electric circuit. In FIG. 1, illustration of the light-transmit ting member 5 is omitted. The LED module A1 is in the form of an elongated rectangle with a longer side extending in the x direction and a shorter side extending in the y direction, as viewed in the z direction.

As shown in FIGS. 1 and 2, the lead 1 includes a terminal portion 11, a die-bonding portion 12, a root sunk portion 15, and a front-end sunk portion 14. The lead 1 is formed by e.g. plating a copper plate which is 0.15 to 0.20 mm in thickness with silver. The terminal portion 11 is exposed to the outside on the left side of the support member 4 in the x direction and used to connect the lead 1 to an external electric circuit. The terminal portion 11 is for sued by bending a portion of the lead 1 which projects from the support member 4.

The lead 1 is bent so that part of it projects upward in the z direction, whereby the die-bonding 12 bulging upward in the direction z relative to other portions is provided. The upper surface of the die-bonding portion 12 in the direction z is a mount surface 12a on which the LED chip 3 is mounted. The mount surface 12a is above the other regions of the lead 1 by about 0.1 mm in the direction z. The lower surface 12b of the die-bonding portion 12 in the z direction is above the lower surfaces of the other regions of the lead 1 and held in close contact with the support member 4. The root sunk portion 15 and the front-end sunk portion 14 are connected to the die-bonding portion 12 and positioned lower than the die-bonding portion 12 in the z direction.

As shown in FIGS. 1 and 2, the lead 2 is spaced apart from the lead 1 in the x direction and includes a terminal portion 21 and a wire-bonding portion 22. The lead 2 is formed by e.g. plating a copper plate which is 0.15 to 0.20 mm in thickness with silver. The terminal portion 21 is exposed to the outside on the right side of the support member 4 in the x direction and used to connect the lead 2 to an external electric circuit. The terminal portion 21 is formed by bending a portion of the lead 2 which projects from the support member 4. The wire-bonding portion 22 is provided at the left end of the lead 2 in the x direction and used for bonding the wire 61.

The LED chip 3 is formed by laminating semiconductor materials such as gallium nitride. The LED chip 3 emits blue light, green light, red light or the like due to recombination of electrons and holes in an active layer sandwiched between an n-type semiconductor layer and a p-type semiconductor layer. The LED chip 3 is provided with an electrode terminal 31 electrically connected to the n-type semiconductor layer and an electrode terminal 32 electrically connected to the p-type semiconductor layer. As shown in FIG. 2, the electrode terminal 31 is provided on the lower end surface of the LED chip 3 in the z direction, whereas the electrode terminal 32 is provided on the upper end surface. For instance, the LED chip 3 is generally in the form of a rectangular parallelepiped having dimensions of e.g. 0.3 mm in the x direction, 0.3 mm in the y direction, and 0.15 mm in the z direction. The LED chip 3 having this structure emits light in almost ail directions except downward in the z direction.

The LED chip 3 is bonded to the mount surface 12a by using a conductive bonding material, not shown, so that the electrode terminal 31 is electrically connected to the die-bonding portion 12. The electrode terminal 32 is connected to the wire-bonding portion 22 via a wire 61. Specifically, the wire 61 is e.g. a gold wire and extends in the x direction. The left end of the wire in the x direction is bonded to the electrode terminal 32, whereas the right end in the x direction is bonded to the wire-bonding portion 22.

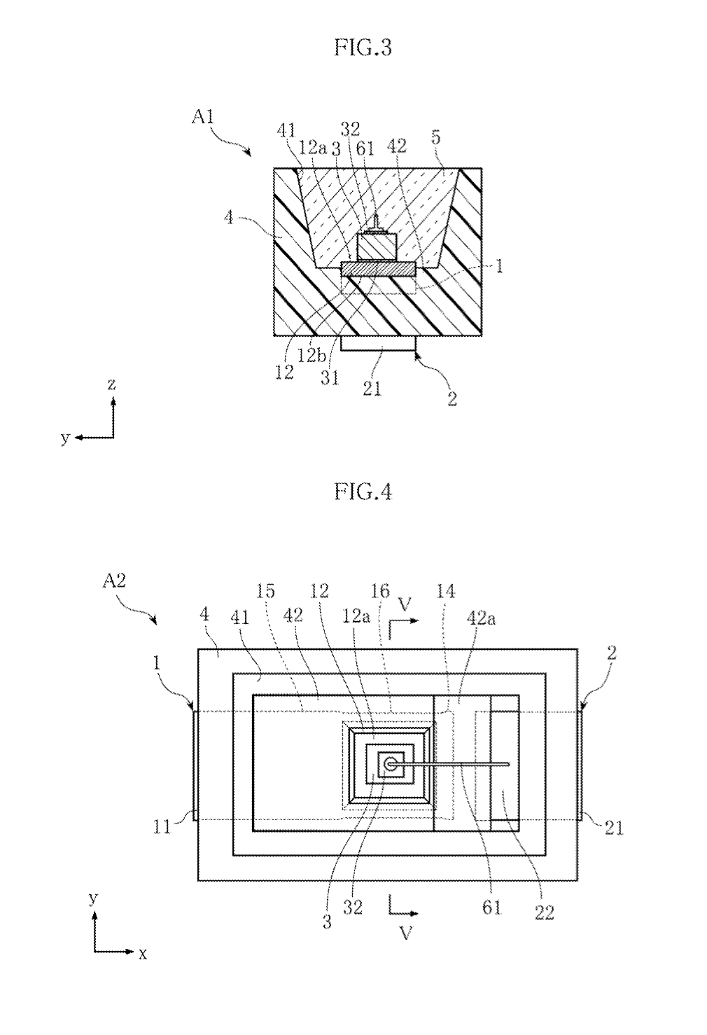

The support member 4 is made of a white epoxy resin in which e.g. titanium oxide is mixed and has a rectangular shape in plan view as shown in FIG. 1. The support member 4 fixes the leads 1 and 2 by covering part of each lead. The support member 4 is recessed at the center and has a reflective surface 41. As shown in FIGS. 2 and 3, the reflective surface 41 is inclined to become further away from the LED chip 3 in the x direction or the y direction as proceeding upward in the z direction. The reflective surface 41 is in the form of a frame surrounding the LED chip 3, as viewed in the z direction. The inner edge of the reflective surface 41 is in the form of an elongated rectangle having a length in the x direction, as viewed in the z direction. The die-bonding portion 12 is arranged at the center in the x direction and the y direction with respect to the inner edge of the reflective surface 41. The reflective surface 41 serves to reflect the light, which is emitted from the LED chip 3 in a direction perpendicular to the z direction, upward in the z direction.

The support member 4 further includes a protective portion 42. The protective portion 42 extends from the inner edge of reflective surface 41 and covers the root sank portion 15 and the front-end sunk portion 14 of the lead 1. The die-bonding portion 12 is exposed from the protective portion 42. The protective portion 42 is about 0.05 mm in thickness. As shown in FIGS. 2 and 3, the protective portion 42 is formed so that its upper surface in the z direction is positioned below the mount surface 12a. The protective portion 42 has, on the right side of the die-bonding portion 12 in the x direction, an inclined portion 42a that becomes thinner in the z direction as proceeding to the right in the x direction. The inclined portion 42a extends over the entire width in the y direction of the inner edge of the reflective surface 41 and over a length of e.g. about 1.0 mm in the x direction. The right end of the inclined portion 42a in the x direction covers the left end of the lead 2 in the x direction. The protective portion 42 exposes the upper surface of the wire-bonding portion 22 in the z direction.

The support member 4 having the above-described structure is made by insert molding using a mold. Specifically, after the leads 1 and 2 are set in a mold, liquid epoxy resin is poured into the mold and then hardened, whereby the support member 4 is obtained.

The light-transmitting member 5 is configured to fill the region surrounded by the reflective surface 41 and covers the die-bonding portion 12, the wire-bonding portion 22, the LED chip 3 and the wire 61 for protection. For instance, the light-transmitting member 5 is made of transparent epoxy resin.

The advantages of the LED module A1 are described below.

According to this embodiment, the leads 1 and 2 are covered by the white protective portion 42 except the region for mounting the LED chip 3. Thus, even when the silver-plated surfaces of the leads 1 and 2 change to a dark color, the dark portion is not excessively exposed. Thus, the color of the light emitted at the start of the use is maintained for a long time. Since the mount surface 12a is above the upper surface of the protective portion 42 in the z direction, light traveling sideways from the LED chip 3 is properly reflected upward in the z direction by the reflective surface 41 without being blocked by the protective portion 42. Thus, the provision of the protective portion 42 does not cause reduction of the light emission amount, and the LED module A1 stably emits light for a long time, whereby a longer lifetime is provided.

Moreover, according to the present embodiment, owing to the provision of the inclined portion 42a, the thickness of the protective portion 42 is small adjacent to the wire-bonding portion 22, This arrangement reduces the possibility that the wire 61 comes into contact with the protective portion 42. In the LED module A1, therefore, breakage of the wire 61 due to contact with the protective portion 42 is unlikely to occur.

Other embodiments of the present invention are described below. In these figures, the elements that are identical or similar to those of the foregoing embodiment are designated by the same reference signs as those used for the foregoing embodiment, and the description are omitted appropriately.

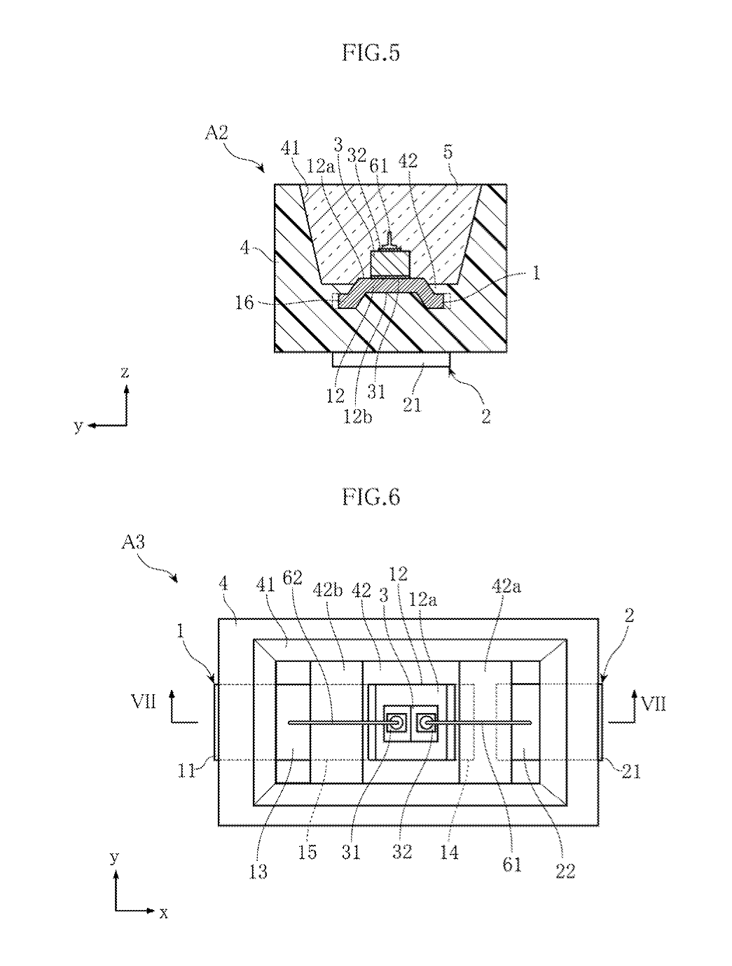

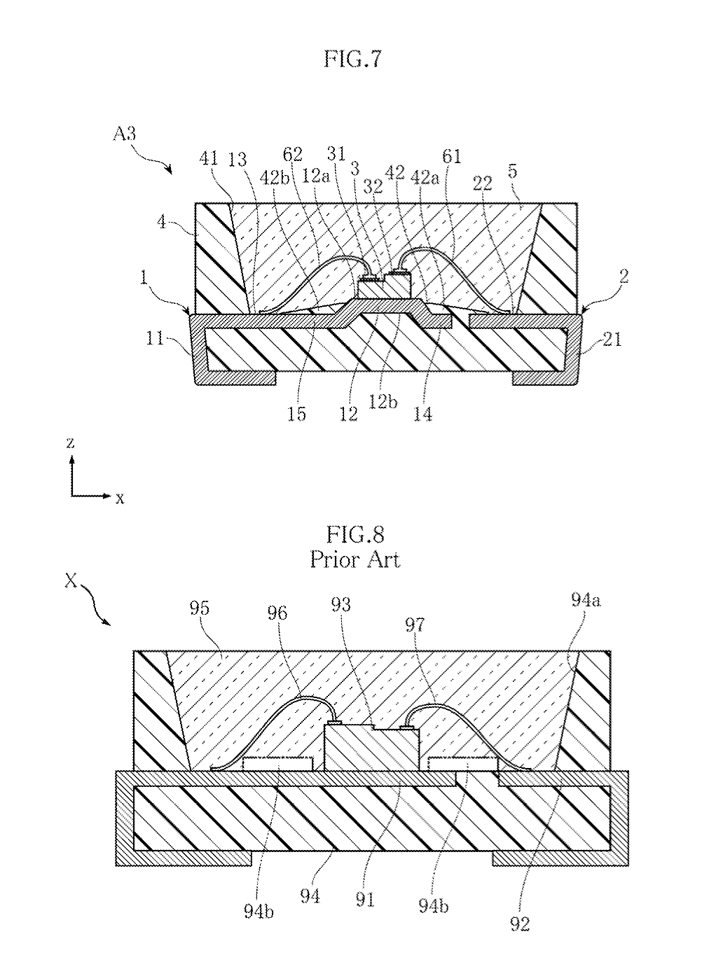

FIGS. 4 and 5 show an LED module A2 according to a second embodiment of the present invention. The LED module A2 differs from the LED module A1 in that the lead 1 includes two side sunk portions 16. Other structures of the LED module A2 are the same as those of LED module A1.

The two side sunk portions 16 are on the two sides of the die-bonding portion 22 in the y direction and below the die-bonding portion 12 in the z direction. The two side sunk portions 16 are covered by the protective portion 42.

The lead 1 having the above-described structure may be formed by e.g. drawing.

According to this arrangement, the area of the mount surface 12a, which is exposed from the protective portion 42, is further reduced. This is advantageous in that effects of color change of the silver-plated surfaces of the lead 1 are reduced. This advantage is especially effective when the dimension of the lead 1 in the y direction is large.

FIGS. 6 and 7 show an LED module A3 according to a third embodiment of the present invention. In the LED module A3, the LED chip 3 is provided with two electrode terminals 31 and 32 on the upper end surface in the z direction, and the lead 1 is provided with a wire-bonding portion 13. Further, the protective portion 42 has an inclined portion 42b. The structures of other parts of the LSD module A3 are the same as those of the LED module A1.

The basic structure of the LED chip 3 is the same as that of the LED module A1. The electrode terminal 31 electrically connected to the n-type semiconductor layer is provided on the left side in the x direction on the upper end surface in the z direction, whereas the electrode terminal 32 electrically connected to the p-type semiconductor layer is provided on the right side in the x direction on the upper end surface in the z direction. The electrode terminal 31 is connected to the wire-bonding portion 13 by a wire 62.

The wire-bonding portion 13 is on the opposite side of the die-bonding portion 12 across the root sunk portion 15 in the y direction and is at the same position as the root sunk portion 15 in the z direction.

The inclined portion 12b is provided between the die-bonding portion 12 and the wire-bonding portion 13 in the x direction and configured to become thinner as proceeding to the left in the x direction. The inclined portion 42b is about 1.0 mm in length in the x direction. The provision of the inclined portion 42b prevents contact, between the protective portion 42 and the wire 62.

With the LED module A3 again, the leads 1 and 2 are covered by the protective portion 42 except the region for mounting the LED chip 3. Thus, effects of color change of the silver-plated surfaces of the leads 1, 2 are reduced. Thus, the color of the light emitted at the start of the use is maintained for a long time. Since the upper surface of the die-bonding portion 12 in the direction z is above the upper surface of the protective portion 42 in the z direction, light traveling sideways from the LED chip 3 is properly reflected upward in the z direction by the reflective surface 41 without being blocked by the protective portion 42. Thus, the provision of the protective portion 42 does not cause reduction of the light emission amount, and the LED module A3 stably emits light for a long time, whereby a longer lifetime is provided.

In the LED module A3 having the above-described structure, a non-conductive resin can be used as a bonding material for bonding the LED chip 3 to the mount surface 12a.

The LED module according to the present invention is not limited to the foregoing embodiments. The specific structure of each part of the LED module according to the present invention can be varied in design in many ways. For instance, although the upper surface of the protective portion 42 in the z direction is below the mount surface 12a in the foregoing embodiments, these surfaces may be at the same position in the z direction. Alternatively, the upper surface of the protective portion 42 in the z direction may be above the mount surface 12a, and the protective portion 42 may lie over the outer edge of the die-bonding portion 12. In this case, it is desirable that the upper end surface of the LED chip 3 in the z direction is above the upper surface of the protective portion 42 in the z direction.

In the foregoing embodiments, the LED chip 3 is bonded to the die-bonding portion 12 provided in the lead 1 in the form of an elongated plate extending in the x direction. However, the shape of the lead 1 can be selected appropriately. Moreover, the outer configuration of the support member 4 can be selected appropriately, and accordingly, the shape of the reflective surface 41 as viewed in the z direction can be changed. For instance, the reflective surface 41 may be annular as viewed in the z direction. In this case, it is desirable to arrange the die-bonding portion 12 at the center of the circle defined by the reflective surface 41.

Moreover, although the reflective surface 41 is at flat surface in the foregoing embodiments, it may be a curved surface. When the reflective surface 41 is a curved surface, it is desirable that reflective surface 41 forms part of a concave mirror with the LED chip 3 positioned at the focal point.

Although the support member 4 is made of white resin in the foregoing embodiments, resin other than white resin can be used as long as it reflects light emitted from the LED chip 3.

Although the electrode terminal 31 electrically connected to the n-type semiconductor layer is connected to the lead 1, whereas the electrode terminal 32 electrically connected to the p-type semiconductor layer is connected to the lead 2 in the LED module A3, these connections may be reversed.

The surfaces of the leads 1 and 2 are plated with silver in the foregoing embodiments. The silver-plating may be applied to both the upper and lower surfaces in the z direction. Alternatively, the silver-plating may be applied only to the upper surfaces of the leads 1 and 2 in the z direction.

1. An LED module comprising:
a first lead including a die-bonding portion provided with a mount surface disposed on one side in a thickness direction;
a second lead including a wire-bonding portion and spaced apart from the first lead, the second lead being arranged such that a thickness direction thereof corresponds to the thickness direction of the first lead;
an LED chip mounted on the mount surface and provided with a first electrode terminal and a second electrode terminal, the first electrode terminal being electrically connected to the first lead, the second electrode terminal being electrically connected to the second lead; and
a support member supporting the first lead and the second lead;
wherein the LED chip includes an end surface disposed on the one side in the thickness direction, and the second electrode terminal is provided on the end surface and connected to the wire-bonding portion by a wire,
the support member includes a protective portion, and the first lead includes a surface disposed on the one side in the thickness direction, the protective portion covering said surface of the first lead in a manner such that the mount surface is exposed, and
the die-bonding portion bulges toward the one side in the thickness direction relative to portions of the first lead that are covered by the protective portion.

2. The LED module according to claim 1, wherein the protective portion includes an inclined portion that becomes thinner as proceeding away from the die-bonding portion in a direction in which the wire extends.

3. The LED module according to claim 2, wherein the inclined portion is configured to overlap a part of the second lead as viewed in the thickness direction.

4. The LED module according to claim 1, wherein the wire-bonding portion is metal-plated on the one side in the thickness direction.

5. The LED module according to claim 1, wherein the first electrode terminal is bonded to the die-bonding portion.

6. The LED module according to claim 1, wherein the first electrode terminal is provided on a portion of the LED chip disposed on the one side in the thickness direction,
the first lead includes a wire-bonding portion connected to the first electrode terminal with an additional wire, and
the protective portion is configured to expose the wire-bonding portion of the first lead.

7. The LED module according to claim 6, wherein the protective portion includes an additional inclined portion that becomes thinner as proceeding away from the die-bonding portion in a direction in which the additional wire extends.

8. The LED module according to claim 6, wherein the wire-bonding portion of the first lead is metal-plated on the one side in the thickness direction.

9. The LED module according to claim 1, wherein the support member is made of a resin that reflects light emitted from the LED chip and the support member includes a reflective surface inclined to become further away from the LED chip in the thickness direction as proceeding away from the LED chip in a direction perpendicular to the thickness direction.

10. The LED module according to claim 9, wherein the reflective surface is in a form of a frame surrounding the LED chip as viewed in the thickness direction, and
the protective portion is connected to the reflective surface.

11. The LED module according to claim 10, wherein the reflective surface includes an inner edge in a form of an elongated rectangle as viewed in the thickness direction, and
the LED chip is arranged at a center in a short-side direction of the inner edge.

12. The LED module according to claim 11, wherein the LED chip is arranged at a center in a longitudinal direction of the inner edge.

13. The LED module according to claim 1, wherein the end surface of the LED chip on the one side in the thickness direction is offset toward the one side in the thickness direction relative to a surface of the protective portion.

14. The LED module according to claim 13, wherein the die-bonding portion is offset toward the one side in the thickness direction relative to the surface of the protective portion.

15. The LED module according to claim 1, wherein the first lead is bent so that a part thereof projects toward the one side in the thickness direction and the projecting part provides the die-bonding portion.

16. An LED module comprising:
a first lead including a die-bonding portion and a root sunk portion, the die-bonding portion being provided with a mount surface disposed on a firs t side in a thickness direction, the root sunk portion being offset toward a second side in the thickness direction relative to the die-bonding portion;
a second lead including a wire-bonding portion and spaced apart from the first lead, the second lead being arranged such that a thickness direction of the wire-bonding portion corresponds to the thickness direction of the bonding portion of the first lead;
an LED chip mounted on the mount surface and including a first electrode terminal and a second electrode terminal, the first electrode terminal being electrically connected to the first lead, the second electrode terminal being disposed on the first side in the thickness direction and electrically connected to the second lead;
a wire connecting the second electrode terminal and the wire-bonding portion to each other; and
a support member supporting the first lead and the second lead and including a protective portion covering the root sunk portion in a manner such that the mount surface is exposed.
